(19) United States
(12) Patent Application Publication
(10) Pub. No.: US 2016/0259010 A1
(43) Pub. Date: Sep. 8, 2016

(54) BATTERY STATE OF CHARGE ESTIMATION APPARATUS AND BATTERY STATE OF CHARGE ESTIMATION METHOD

(71) Applicant: Yazaki Corporation, Tokyo (JP)

(72) Inventor: Takahiro Syouda, Susono-shi (JP)

(21) Appl. No.: 15/155,377

(22) Filed: May 16, 2016

Related U.S. Application Data
(63) Continuation of application No. PCT/JP2014/082639, filed on Dec. 10, 2014.

(30) Foreign Application Priority Data
Dec. 17, 2013 (JP) 2013-259770

(51) Int. Cl. G01R 31/36

(52) U.S. Cl. CPC G01R 31/3624; G01R 31/3675; G01R 31/3651

(57) ABSTRACT

Battery state-of-charge estimation apparatus detects current-passage state of charging/discharging current through a secondary battery just before passage of current stops, measures voltage value between both electrodes of the secondary battery after passage of charging/discharging current stops, measures elapsed time from when passage of charging/discharging current stops to when voltage value between both electrodes of the secondary battery is measured, estimates open-circuit voltage value using the detected current-passage state, the measured voltage value, the measured elapsed time, and open-circuit voltage value relationship information which relates to relationship between transition of voltage value between both electrodes of the secondary battery after passage of current stops and the open-circuit voltage value of the secondary battery and which is prepared for each current-passage state just before passage of charging/discharging current stops and previously stored in ROM of control unit. State of charge of the battery is estimated based on the estimated open-circuit voltage value.

### TECHNICAL FIELD

The present invention relates to a battery state of charge estimation apparatus and a battery state of charge estimation method that estimate the state of charge of a battery.

### BACKGROUND ART

A secondary battery such as a lithium-ion rechargeable battery or a nickel-hydrogen rechargeable battery is installed as a power source for an electric motor in various vehicles, for example, an electric vehicle (EV) that uses an electric motor to run and a hybrid electric vehicle (HEV) that uses an engine and an electric motor to run. An estimation apparatus that estimates the state of charge of the secondary battery described above (namely, the present amount of power stored in the battery compared with the maximum power storage capacity of the battery) is disclosed, for example, in Patent Literature 1.

The battery state of charge estimation apparatus disclosed in Patent Literature 1 calculates a current integration method-based state of charge SOCi from an accumulated value of the charging or discharging current values of the battery and the feedback-input state of charge SOC of the battery, and calculates a current-integration-method variance Qi in accordance with the information about the accuracy of detection of the charging or discharging current value. Meanwhile, the apparatus calculates an open circuit voltage method-based state of charge SOCv from an open circuit voltage value estimated by applying the charging or discharging current value and the terminal voltage value of the battery to a battery equivalent circuit model, and calculates an open-circuit-voltage-method variance Qv in accordance with the information about the accuracy of detection of the charging or discharging current value and the accuracy of detection of the terminal voltage value V. Then, the apparatus estimates the error in the current integration method-based state of charge SOCi from the difference between the current integration method-based state of charge SOCi and the open circuit voltage method-based state of charge SOCv, the current-integration-method variance Qi, and the open-circuit-voltage-method variance Qv. Then, the apparatus calculates the state of charge of the battery from the estimated error and the current integration method-based state of charge SOCi.

### CITATION LIST

### Patent Literature

Patent Literature 1: Japanese Patent Application Publication No. H9-54147

### SUMMARY OF INVENTION

### Technical Problem

For example, when a charging current I that is a current value Ic passes and the passage of the current stops, the voltage v between both electrodes of a secondary battery generated by the electromotive force of the secondary battery decreases gradually for several minutes to several hours after reaching a voltage value Vc higher than an open circuit voltage value OCV (Open circuit Voltage) that is a true output voltage value, and returns to the open circuit voltage value OCV as illustrated in FIG. 7 due to the characteristics of the secondary battery. When a discharging current passes, the voltage v varies in a similar manner.

Thus, for example, when the voltage v between both electrodes of the secondary battery is measured while the passage of the charging current I that is the current value Ic stops and the voltage v between both electrodes of the secondary battery varies toward the open circuit voltage value OCV, this measurement results in a voltage value including an error in the open circuit voltage value OCV. Furthermore, the state of charge estimation apparatus is configured in consideration of the voltage value between the terminals generated by the passage of the charging or discharging current through the internal resistance of the battery that is a secondary battery. However, the variation in the voltage value between the terminals generated by the electromotive force of the battery is not considered. The measured open circuit voltage value of the battery may include an unconsidered error. For example, an offset error of the current sensor is also accumulated in a method in which the state of charge is detected with a current integration method. In light of the foregoing, there is room to improve the accuracy of detection of the state of charge of a battery in the conventional state of charge estimation apparatus.

An objective of the present invention is to solve the problems described above.

In other words, an objective of the present invention to provide a battery state of charge estimation apparatus and a battery state of charge estimation method capable of improve the accuracy of estimation of the state of charge.

### Solution to Problem

In order to achieve the object, the present invention according to a first aspect provides a battery state of charge estimation apparatus that estimates a state of charge of a battery, and the apparatus includes: a current-passage state detection section that detects a current-passage state, the current-passage state corresponding to an accumulated amount of charging or discharging current flowing through the battery for a predetermined period of time just before passage of the current stops; a voltage value measurement section that measures a voltage value between both electrode of the battery after the passage of the current is stopped; an elapsed time measurement section that measures an elapsed time from a time when the passage of the current is stopped to a time when the voltage value is measured by the voltage value measurement section; a relationship information storage section that previously stores open circuit voltage value relationship information, the open circuit voltage value relationship information being prepared for each of a plurality of the current-passage states just before the passage of the current stops, the open circuit voltage value relationship information being about a relationship between transition of the voltage value between both electrode of the battery after the passage of the current is stopped and an open circuit voltage value of the battery; an open circuit voltage value estimation section that estimates the open circuit voltage value with the current-passage state detected with the current-passage state detection section, the voltage value measured with the voltage value measurement section, the elapsed time measured with the elapsed time measurement section, and the open circuit voltage value relationship information stored in the relationship information storage section; and a state of charge estimation section that estimates the state of charge of the battery in accordance with the open circuit voltage value estimated with the open circuit voltage value estimation section.

In order to achieve the object, the present invention according to a second aspect provides a battery state of charge estimation apparatus that estimates a state of charge of a battery, and the apparatus includes: a current-passage state detection section that detects a current-passage state, the current-passage state corresponding to an accumulated amount of charging or discharging current flowing through the battery for a predetermined period of time just before passage of the current stops; a voltage value measurement section that measures a voltage value between both electrodes of the battery when a predetermined measurement waiting period elapses from a time when the passage of the current is stopped; a relationship information storage section that previously stores open circuit voltage value relationship information, the open circuit voltage value relationship information being prepared for each of a plurality of the current-passage states just before the passage of the current stops, the open circuit voltage value relationship information being about a relationship between the voltage value between both electrode of the battery when the measurement waiting period elapses from the time when the passage of the current is stopped and an open circuit voltage value of the battery; an open circuit voltage value estimation section that estimates the open circuit voltage value with the current-passage state detected with the current-passage state detection section, the voltage value measured with the voltage value measurement section, and the open circuit voltage value relationship information stored in the relationship information storage section; and a state of charge estimation section that estimates the state of charge of the battery in accordance with the open circuit voltage value estimated with the open circuit voltage value estimation section.

According to a third aspect of the invention, the battery state of charge estimation apparatus further including a temperature measurement section that measures a temperature of the battery, wherein the relationship information storage section further stores the open circuit voltage value relationship information for each of the temperatures of the battery, and the open circuit voltage value estimation section also uses the temperature measured with the temperature measurement section to estimate the open circuit voltage value.

According to a fourth aspect, the battery state of charge estimation apparatus further including a state of health detection section that detects a state of health (i.e., degradation state) of the battery, wherein the relationship information storage section further stores the open circuit voltage value relationship information for each of the states of health of the battery, and the open circuit voltage value estimation section also uses the state of health detected with the state of health detection section to estimate the open circuit voltage value.

In order to achieve the object, the invention provides, according to a fifth aspect, a battery state of charge estimation method for estimating a state of charge of a battery, and the method includes: detecting a current-passage state, the current-passage state corresponding to an accumulated amount of charging or discharging current flowing through the battery for a predetermined period of time just before passage of the current stops; measuring a voltage value between both electrodes of the battery after the passage of the current stop is stopped; measuring an elapsed time from a time when the passage of the current is stopped to a time when the voltage value is measured in the voltage value measurement; estimating an open circuit voltage value with the current-passage state detected in the current-passage state detection, the voltage value measured in the voltage value measurement, the elapsed time measured in the elapsed time measurement, and open circuit voltage value relationship information, the open circuit voltage value relationship information being prepared for a current-passage state or each of a plurality of current-passage states just before the passage of the current stops, the open circuit voltage value relationship information being previously stored in a storage section, the open circuit voltage value relationship information being about a relationship between transition of the voltage value between both electrodes of the battery after the passage of the current is stopped and the open circuit voltage value of the battery; and estimating the state of charge of the battery in accordance with the open circuit voltage value estimated in the open circuit voltage value estimation.

### Advantageous Effects of Invention

According to the first to fifth aspects of the invention, the current-passage state is detected. The current-passage state is, for example, the accumulated amount of the charging or discharging current or the intensity of the current just before the passage of the current through the battery stops. The voltage value between both electrodes of the battery after the passage of the charging or discharging current is stopped is measured. The elapsed time from the time when the passage of the charging or discharging current is stopped to the time when the voltage value between both electrodes of the battery is measured, is measured. The open circuit voltage value is estimated with the detected current-passage state, the measured voltage value, the measured elapsed time, and the open circuit voltage value relationship information. The open circuit voltage value relationship information is prepared for a current-passage state or each of a plurality of current-passage states just before the passage of the charging or discharging current stops, and is previously stored in a storage unit. The open circuit voltage value relationship information is about the relationship between the transition of the voltage value between both electrodes of the battery after the passage of the current is stopped and the open circuit voltage value of the battery. Then, the state of charge of the battery is estimated in accordance with the estimated open circuit voltage value.

The estimation as described above allows for the acquisition of an open circuit voltage value with a high degree of accuracy in consideration of the variation in voltage between both electrodes of the battery generated by the electromotive force of the battery after the passage of the current is stopped, for example, by previously obtaining, from a preliminary measurement or a simulation, the relationship between the transition of the voltage value between both electrodes of the battery after the passage of the charging or discharging current is stopped and the open circuit voltage value of the battery, and estimating the open circuit voltage value of the battery from the relationship information about the relationship because the relationship has repeatability. Thus, estimating the state of charge of the battery in accordance with the estimated open circuit voltage value can further improve the accuracy of estimation of the state of charge.

According to the second aspect of the invention, the current-passage state is detected. The current-passage state is, for example, the accumulated amount of current or the intensity of current just before the passage of the charging or discharging current through the battery stops. The voltage value between both electrodes of the battery when a predetermined measurement waiting period elapses from the time when the passage of the charging or discharging current has stopped is measured. The open circuit voltage value is estimated with the detected current-passage state, the measured voltage value, and the open circuit voltage value relationship information. The open circuit voltage value relationship information is prepared for a current-passage state or each of a plurality of current-passage states just before the passage of the current stops, and is previously stored in a storage unit. The open circuit voltage value relationship information is about the relationship between the voltage value between both electrodes of the battery when the measurement waiting period elapses from the time when the passage of the current is stopped and the open circuit voltage value of the battery. Then, the state of charge of the battery is estimated in accordance with the estimated open circuit voltage value.

The estimation as described above allows for the acquisition of an open circuit voltage value with a high degree of accuracy in consideration of the variation in voltage between both electrodes of the battery generated by the electromotive force of the battery after the passage of the current is stopped, for example, by previously obtaining, from a preliminary measurement or a simulation, the relationship between the voltage value between both electrodes of the battery when the measurement waiting period elapses from the time when the passage of the charging or discharging current is stopped and the open circuit voltage value of the battery, and estimating the open circuit voltage value of the battery from the relationship information about the relationship because the relationship has repeatability. Thus, estimating the state of charge of the battery in accordance with the estimated open circuit voltage value can further improve the accuracy of estimation of the state of charge.

According to the third aspect of the invention, the temperature of the battery is also measured. The open circuit voltage value relationship information is prepared for each of the temperatures of the battery, and is stored in a storage unit. Then, the measured temperature is also used to estimate the open circuit voltage value. This allows for the acquisition of the open circuit voltage value with a higher degree of accuracy by estimating the open circuit voltage value also in consideration of the temperature of the battery because the voltage value between both electrodes of a battery relates also to the temperature of the battery. Thus, estimating the state of charge of the battery in accordance with the estimated open circuit voltage value can further improve the accuracy of estimation of the state of charge.

According to the fourth aspect of the invention, the state of health of the battery is also detected. The open circuit voltage value relationship information for each of the states of health of the battery is prepared, and is stored in a storage unit. Then, the detected state of health is also used to estimate the open circuit voltage value. This allows for the acquisition of the open circuit voltage value with a higher degree of accuracy by estimating the open circuit voltage value also in consideration of the state of health of the battery because the voltage value between both electrodes of a battery relates also to the state of health of the battery. Thus, estimating the state of charge of the battery in accordance with the estimated open circuit voltage value can further improve the accuracy of estimation of the state of charge.

### BRIEF DESCRIPTION OF DRAWINGS

FIG. 1 is a diagram of a schematic configuration of a battery state of charge estimation apparatus according to an embodiment of the present invention;

FIG. 2 is a schematic diagram of exemplary open circuit voltage value relationship information previously stored in a ROM of a control unit included in the battery state of charge estimation apparatus illustrated in FIG. 1;

FIG. 3 is a flowchart of an exemplary battery state of charge estimation process performed with the control unit included in the battery state of charge estimation apparatus illustrated in FIG. 1;

FIG. 4 is a flowchart of an exemplary battery-state detection process performed with the control unit included in the battery state of charge estimation apparatus illustrated in FIG. 1;

FIG. 5 is a schematic diagram of the waveform of the voltage between both electrodes of a secondary battery and the waveforms of the currents flowing through the secondary battery during the battery-state detection process illustrated in FIG. 4;

FIG. 6 is a schematic diagram of exemplary state of charge relationship information about the relationship between the open circuit voltage value and state of charge of the secondary battery; and

FIG. 7 is a schematic diagram of the waveform of the voltage between both electrodes of the secondary battery after a charging current is stopped.

### DESCRIPTION OF EMBODIMENTS

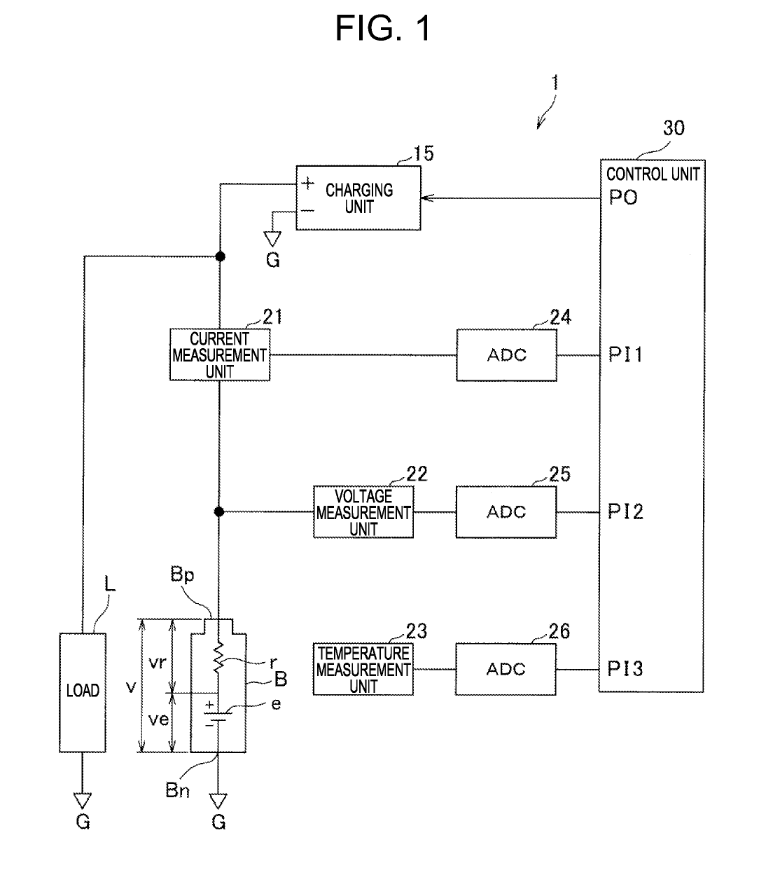

A battery state of charge estimation apparatus according to an embodiment of the present invention will be described hereinafter with reference to FIGS. 1 to 6.

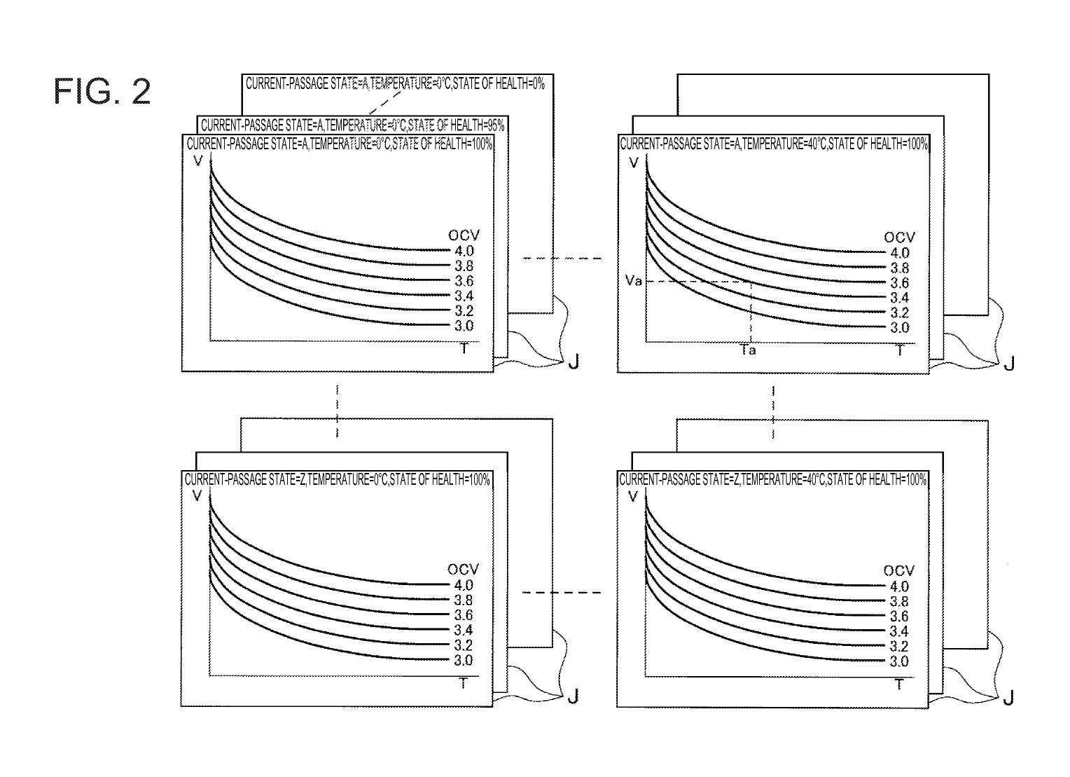

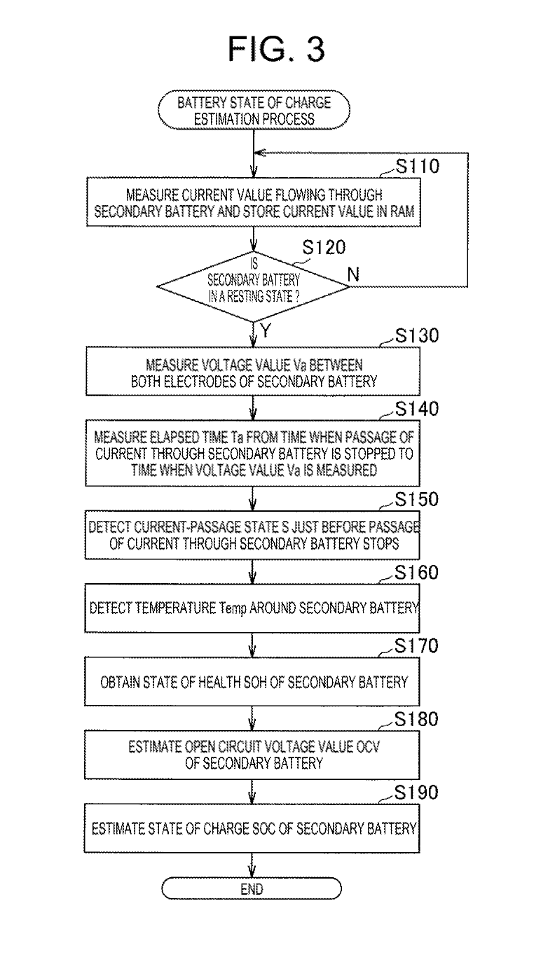

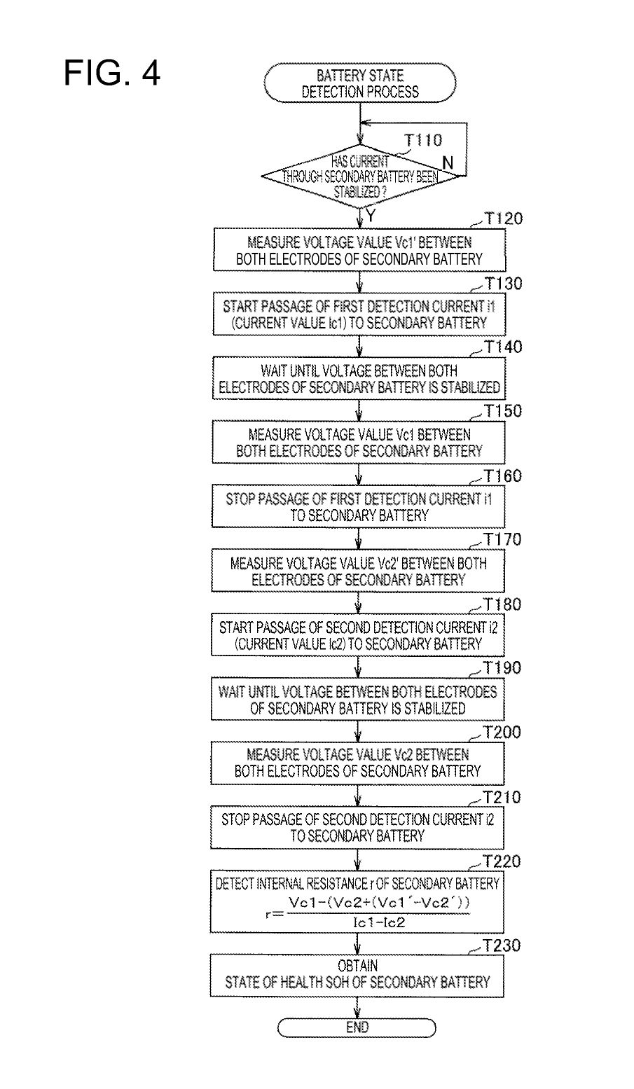

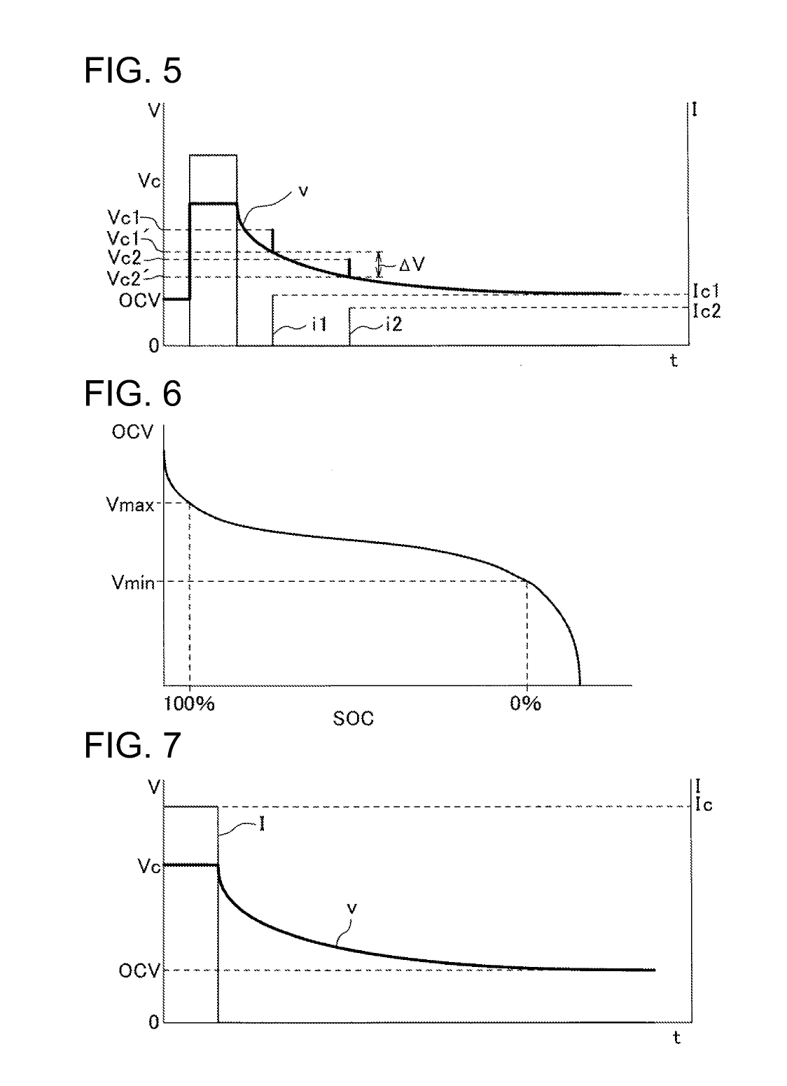

FIG. 1 is a diagram of a schematic configuration of a battery state of charge estimation apparatus according to an embodiment of the present invention. FIG. 2 is a schematic diagram of exemplary open circuit voltage value relationship information previously stored in a ROM of a control unit included in the battery state of charge estimation apparatus illustrated in FIG. 1. FIG. 3 is a flowchart of an exemplary battery state of charge estimation process performed with the control unit included in the battery state of charge estimation apparatus illustrated in FIG. 1. FIG. 4 is a flowchart of an exemplary battery-state detection process performed with the control unit included in the battery state of charge estimation apparatus illustrated in FIG. 1. FIG. 5 is a schematic diagram of the waveform of the voltage between both electrodes of a secondary battery and the waveforms of the currents flowing through the secondary battery during the battery-state detection process illustrated in FIG. 4. FIG. 6 is a schematic diagram of exemplary state of charge relationship information about the relationship between the open circuit voltage value and state of charge of the secondary battery.

The battery state of charge estimation apparatus according to the present embodiment is installed, for example, in an electric vehicle and used to estimate the state of charge of a secondary battery included in the electric car. Needless to say, the battery state of charge estimation apparatus is applicable, for example, to a device or system including a secondary battery, other than the electric car. Alternatively, the battery state of charge estimation apparatus is applicable, for example, to a device or system including a primary battery instead of the secondary battery. The state of charge is, for example, the ratio of the amount of current that is currently stored to the storage capacity of current (SOCi), or the ratio of the present amount of stored power to the power storage capacity (SOCp). However, any type of state of charge can be estimated. In this embodiment, the term of the state of charge (SOC) is used collectively.

As illustrated in FIG. 1, the battery state of charge estimation apparatus according to the present embodiment (illustrated with a reference sign 1 in the drawing) is connected to a secondary battery B installed in an electric vehicle (not illustrated) to estimate a state of charge SOC of the secondary battery B.

The secondary battery B includes an electromotive force unit e that generates voltage, and an internal resistance r. The secondary battery B generates a voltage v between both electrodes (a positive electrode Bp and a negative electrode Bn). The voltage v is determined in accordance with a voltage value ve and a voltage value vr (v=ve+vr). The voltage value ve is generated by the electromotive force exerted by the electromotive force unit e. The voltage value vr is generated by the current flowing through the internal resistance r. An open circuit voltage value OCV of the secondary battery B is a true voltage value ve that the electromotive force unit e generates. The secondary battery B is connected to a load L, for example, a motor installed in the electric vehicle. The voltage value generated with the electromotive force unit e varies depending on the current passed through the secondary battery B, and returns to a true value as the time elapses after the passage of the current is stopped. The variation in the voltage value (for example, the amount of variation in voltage from the open circuit voltage value OCV, or the time required to return to the open circuit voltage value OCV) depends on the current-passage state such as the accumulated amount or intensity of the current passed through the secondary battery B. The variation in the voltage has repeatability.

The battery state of charge estimation apparatus 1 according to the present embodiment includes a charging unit 15, a current measurement unit 21, a voltage measurement unit 22, a temperature measurement unit 23, a first analog-digital converter 24, a second analog-digital converter 25, a third analog-digital converter 26, and a control unit 30.

The charging unit 15 includes, for example, a power supply device capable of outputting the charging current of an arbitrary current value to the secondary battery B by receiving the power from an external power supply connected to the electric vehicle. The charging unit 15 includes a pair of output terminals, which are connected to the positive electrode Bp and negative electrode Bn of the secondary battery B, respectively. The control unit 30 to be described below controls the charging unit 15 to output a charging current Ic of a constant current value so as to charge the secondary battery B. The charging unit 15 further outputs a first detection current i1 that is a current value Ic1 and a second detection current i2 that is a current value Ic2 in a battery-state detection process for detecting the state of health SOH of the secondary battery B to be described below. The first detection current i1 and second detection current i2 flow in a charging direction in which the battery is charged (a direction in which the current flows into the secondary battery B) when the state of health SOH is detected (note that Ic2≠Ic1 holds).

The first detection current i1 and second detection current i2 output from the charging unit 15 are a single rectangular wave (pulse wave). The pulse height (current value) and pulse width are not large enough to affect the state in which the secondary battery B is charged (namely, the voltage ve of the electromotive force unit e). The first detection current i1 and second detection current i2 can form a waveform other than the rectangular wave, such as a triangle wave, a saw-tooth wave, or a sine wave.

The current measurement unit 21 is provided in series between a first terminal of the charging unit 15 and the positive electrode Bp of the secondary battery B so as to measure the current value flowing in the charging direction or a discharging direction in which the secondary battery B discharges, and output a signal (a current signal) causing the voltage to vary depending on the current value.

The voltage measurement unit 22 outputs a signal (a voltage signal) corresponding to the voltage between the positive electrode Bp and negative electrode Bn of the secondary battery B. In the present embodiment, the voltage measurement unit 22 is formed by a plurality of fixed resistors that divide the voltage between both electrodes of the secondary battery B so that the voltage is within the voltage range in which the voltage can be input to the second analog-digital converter 25 to be described below.

The temperature measurement unit 23 includes, for example, a temperature detecting device such as a thermistor device. The temperature measurement unit 23 is in contact with the secondary battery B or is placed near the secondary battery B, and outputs a signal (a temperature signal) causing the voltage to vary depending on the temperature of the secondary battery B.

The first analog-digital converter 24 (hereinafter, referred to as a “first ADC 24”) quantizes a current signal output from the current measurement unit 21, and outputs a signal indicating a digital value corresponding to the voltage value in the current signal. Similarly, the second analog-digital converter 25 (hereinafter, referred to as a “second ADC 25”) quantizes a voltage signal output from the voltage measurement unit 22, and outputs a signal indicating a digital value corresponding to the voltage value in the voltage signal. Similarly, the third analog-digital converter 26 (hereinafter, referred to as a “third ADC 26”) quantizes a temperature signal output from the temperature measurement unit 23, and outputs a signal indicating a digital value corresponding to the voltage value in the temperature signal. The first ADC 24, the second ADC 25, and the third ADC 26 are implemented as individual electronic units in the present embodiment. However, the implementation is not limited to the embodiment. For example, an analog-digital converter embedded in the control unit 30 to be described below can be used to quantize each of the signals.

The control unit 30 includes a microcomputer embedding, for example, a CPU, a ROM, a RAM, and a timer so as to control the entire battery state of charge estimation apparatus 1. The ROM previously stores control programs to cause the CPU to function as a current-passage state detection section, a voltage value measurement section, an elapsed time measurement section, an open circuit voltage value estimation section, a state of charge estimation section, a state of health detection section, and a temperature measurement section. The CPU functions as the various sections by executing the control programs.

The ROM in the control unit 30 previously stores an open circuit voltage value relationship information J about the relationship between the transition of the voltage value between both electrodes of the secondary battery B after the passage of the charging or discharging current through the battery is stopped and the open circuit voltage value OCV. The charging or discharging current is the current flowing through the secondary battery B in the charging direction or in the discharging direction. Applying the voltage value Va between both electrodes of the secondary battery B, which is measured after the passage of the current is stopped, and the elapsed time Ta, which elapses from the time when the passage of the current is stopped to the time when the voltage value is measured, to the open circuit voltage value relationship information J can calculate the open circuit voltage value OCV of the secondary battery B. As schematically illustrated in FIG. 2, a plurality of patterns of the open circuit voltage value relationship information J is prepared for (1) the current-passage states S just before the passage of the charging or discharging current through the secondary battery B stops, (2) the temperatures Temp of the secondary battery B, and (3) the states of health SOH of the secondary battery B, respectively.

In the present embodiment, the current-passage state S is the accumulated amount of the current flowing through the secondary battery B for a predetermined period of time (for example, ten seconds) just before the passage of the current stops. Current-passage states S=A to Z are applied to predetermined accumulated amounts, respectively. A plurality of types of open circuit voltage value relationship information J is previously prepared for the current-passage states S, respectively. Similarly, a plurality of types of open circuit voltage value relationship information J, which correspond to the range of the temperatures Temp=0 to 40° C. of the secondary battery B, and to the range of the states of health SOH=0 to 100%, are previously created. In other words, the types of open circuit voltage value relationship information J are formed into a three-dimensional matrix shape in accordance with the current-passage states S, the temperatures Temp, and the states of health SOH. The current-passage state S can be a parameter other than the accumulated amount as long as the parameter relates to the transition of the voltage value between both electrodes of the secondary battery B after the passage of the current is stopped. The types of open circuit voltage value relationship information J are previously created, for example, by a preliminary measurement or simulation, and are stored in the ROM. The ROM is equivalent to the relationship information storage section.

The control unit 30 includes an output port PO connected to the charging unit 15. The CPU in the control unit 30 transmits a control signal to the charging unit 15 via the output port PO to control the charging unit 15.

The control unit 30 includes an input port PH to which a signal from the first ADC 24 is input, an input port PI2 to which a signal from the second ADC 25 is input, and an input port PI3 to which a signal from the third ADC 26 is input. The signals input to the input port PH, the input port PI2, and the input port PI3 in the control unit 30 are converted into the information in a format that the CPU can recognize and transmitted to the CPU. In accordance with the converted information, the CPU measures the current value flowing through the secondary battery B, the voltage value between both electrodes of the secondary battery B, and the temperature of the secondary battery B.

A communication port of the control unit 30 is connected to an in-vehicle network (not illustrated and, for example, a Controller Area Network (CAN)), and thus connected to a display device such as a combination meter of the vehicle via the in-vehicle network. The CPU of the control unit 30 transmits the estimated state of charge SOC of the secondary battery B to the display device via the communication port and the in-vehicle network to display the state of charge SOC of the secondary battery B in accordance with the transmitted signal on the display device.

An exemplary battery state of charge estimation process performed with the control unit 30 included in the battery state of charge estimation apparatus 1 will be described next with reference to the flowchart in FIG. 3. In the battery state of charge estimation process, the state of charge SOC of the secondary battery B is estimated in consideration of the variation in the voltage between both electrodes after the passage of the current through the secondary battery B is stopped, using the open circuit voltage value relationship information J.

In the battery state of charge estimation process, the control unit 30 measures the current values of the current flowing through the secondary battery B in accordance with the current signal input from the current measurement unit 21 via the first ADC 24, and sequentially stores the measured values in the RAM (S110), and the control unit 30 determines whether the measured current value is zero (S120). When the current value is not zero, the control unit 30 continues measuring the current value (N in S120). When the current value is zero, the control unit 30 determines that the passage of the charging or discharging current through the secondary battery B is stopped and became in a resting state, and starts measuring the time with the timer (Y in S120).

Next, when the secondary battery B is in a resting state, the control unit 30 measures the voltage value Va between both electrodes of the secondary battery B in accordance with the voltage signal input from the voltage measurement unit 22 via the second ADC 25 (S130). Meanwhile, the control unit 30 measures, using the timer, the elapsed time Ta from the time when the charging or discharging current through the secondary battery B is stopped to the time when the voltage value Va is measured, and stops the timer (S140).

Next, in accordance with the current values sequentially stored in the RAM, the control unit 30 detects the current-passage state S just before the passage of the charging or discharging current through the secondary battery B stops (S150). As described above, the current-passage state S is the accumulated amount of the current that flows through the secondary battery B for a predetermined period of time (for example, ten seconds) just before the passage of the current stops. The control unit 30 measures the temperature Temp of the secondary battery B in accordance with the voltage signal input from the temperature measurement unit 23 via the third ADC 26 (S160). The control unit 30 obtains the state of health SOH of the secondary battery B detected in a battery-state detection process described below (S170). The state of health SOH is stored in the RAM in the battery-state detection process.

Next, the control unit 30 estimates the open circuit voltage value OCV of the secondary battery B by selecting a type of open circuit voltage value relationship information J among the types of open circuit voltage value relationship information J stored in the ROM in accordance with the current-passage state S, the temperature Temp, and the state of health SOH, and applying the voltage value Va and the elapsed time Ta to the selected open circuit voltage value relationship information J (S180).

Subsequently, the control unit 30 estimates the state of charge SOC of the secondary battery B in accordance with the open circuit voltage value OCV of the secondary battery B (S190). In the present embodiment, the open circuit voltage value OCV of the secondary battery B includes a charge termination voltage Vmax of 4.0 V and a discharge termination voltage Vmin of 3.0 V. The open circuit voltage value OCV linearly varies between the charge termination voltage Vmax and the discharge termination voltage Vmin, relative to the state of charge SOC. In other words, the open circuit voltage value OCV of the secondary battery B is 4.0 V while the state of charge SOC is 100%. The open circuit voltage value OCV is 3.5 V while the state of charge SOC is 50%. The open circuit voltage value OCV is 3.0 V while the state of charge SOC is 0%. Needless to say, this is an example. Instead of the example, for example, when the open circuit voltage value OCV and state of charge SOC of the secondary battery B do not linearly vary as illustrated in FIG. 6, the state of charge relationship information is previously created in accordance with a preliminary measurement or a simulation, and is stored in the ROM. The state of charge relationship information is, for example, a table and is about the relationship between the open circuit voltage value OCV and the state of charge SOC. This enables the control unit 30 to estimate the state of charge SOC by applying the estimated open circuit voltage value OCV to the state of charge relationship information. Then, the process of the present flowchart is terminated.

The process in step S130 of the flowchart in FIG. 3 is an operation for measuring the voltage value. The control unit 30 functions as a voltage value measurement section by performing the process in step S130. The process in step S140 is an operation for measuring the elapsed time. The control unit 30 functions as an elapsed time measurement section by performing the process in step S140. The process in step S150 is an operation for detecting the current-passage state. The control unit 30 functions as a current-passage state detection section by performing the process in step S150. The process in step S160 is an operation for measuring the temperature. The control unit 30 functions as a temperature measurement section by performing the process in step S160. The process in step S170 is an operation for detecting the state of health. The control unit 30 functions as a state of health detection section by performing the process in step S170. The process in step S180 is an operation for estimating the open circuit voltage value. The control unit 30 functions as an open circuit voltage value estimation section by performing the process in step S180. The process in step S190 is an operation for estimating the state of charge. The control unit 30 functions as a state of charge estimation section by performing the process in step S190.

An exemplary battery-state detection process for detecting the state of health SOH of the secondary battery B will be described next with reference to the flowchart in FIG. 4.

The battery-state detection process is an independent process and different from the battery state of charge estimation process, and is performed at a time different from the battery state of charge estimation process. In the battery-state detection process, the state of health SOH of the secondary battery B is detected also in consideration of the variation in the voltage between both electrodes after the passage of current through the secondary battery B is stopped.

It is known that a secondary battery deteriorates and the power storage capacity (for example, the current capacity or the power capacity) and the output performance gradually decrease as the charge and discharge are repeated. For example, the State of Health (SOH) that is the ratio of the present power storage capacity to the initial power storage capacity, or the State of Function (SOF) that is the ratio of the present output performance to the initial output performance is used as the index of the state (deterioration) of the secondary battery. It is known that the SOH or SOF correlates with the internal resistance of a secondary battery. Thus, by finding the internal resistance of the secondary battery, the SOH or SOF can be detected in accordance with the found internal resistance. The SOH of the secondary battery B is detected in the battery-state detection process to be described below.

In the battery-state detection process, the control unit 30 measures the current value of the current flowing through the secondary battery B several times in accordance with the current signal input from the current measurement unit 21 via the first ADC 24, and waits until the current values measured within a predetermined period of time (for example, for a minute) become identical (have the values within a predetermined error range (for example, ±3%)) (N in T110). When the current values are identical, the control unit 30 determines that the current flowing through the secondary battery B became stable (is stopped, when the current values are zero) (Y in T110).

Next, the control unit 30 measures a voltage value Vc1′ of the voltage v between both electrodes of the secondary battery B in accordance with the voltage signal input from the voltage measurement unit 22 via the second ADC 25 (T120).

Next, the control unit 30 transmits a control signal to the charging unit 15 just after measuring the voltage value Vc1′ so as to start the passage of the first detection current i1 (the current value Ic1) from the charging unit 15 to the secondary battery (T130).

Next, the control unit 30 waits until a predetermined voltage stabilization time (for example, for a second) required to stabilize the voltage v between both electrodes of the secondary battery B elapses (T140), and measures the voltage value Vc1 of the voltage v between both electrodes of the secondary battery B after the voltage stabilization time elapses (T150).

Next, the control unit 30 transmits a control signal to the charging unit 15 so as to stop the passage of the first detection current i1 from the charging unit 15 to the secondary battery B (T160).

Next, the control unit 30 measures a voltage value Vc2′ of the voltage v between both electrodes of the secondary battery B in accordance with the voltage signal input from the voltage measurement unit 22 via the second ADC 25 (T170).

Next, the control unit 30 transmits a control signal to the charging unit 15 just after measuring the voltage value Vc2′ so as to start the passage of the second detection current i2 (the current value Ic2) from the charging unit 15 to the secondary battery B (T180).

Next, the control unit 30 waits until the voltage stabilization time required to stabilize the voltage v between both electrodes of the secondary battery B elapses (T190), and measures the voltage value Vc2 of the voltage v between both electrodes of the secondary battery B after the voltage stabilization time elapses (T200).

Next, the control unit 30 transmits a control signal to the charging unit 15 so as to stop the passage of the second detection current i2 from the charging unit 15 to the secondary battery B (T210).

Next, the control unit 30 calculates the variation ΔV (ΔV=Vc1′−Vc2′) in the voltage component generated by the electromotive force of the secondary battery B in the voltage value between both electrodes of the secondary battery B generated in the period from the passage of the first detection current i1 to the passage of the second detection current i2, in accordance with the voltage value Vc1′ between both electrodes of the secondary battery B just before the passage of the first detection current i1 starts and the voltage value Vc2′ between both electrodes of the secondary battery B just before the passage of the second detection current i2 starts. Then, the control unit 30 detects the internal resistance r of the secondary battery B in accordance with the current value Ic1 of the first detection current i1, the voltage value Vc1 between both electrodes of the secondary battery B when the first detection current i1 passes, the current value Ic2 of the second detection current i2, the voltage value Vc2 between both electrodes of the secondary battery B when the second detection current i2 passes, and the variation ΔV, using the following calculation expression (T220).

$$\begin{matrix}r = ( Vc 1 - ( Vc 2 + Δ V ) ) / ( Ic 1 - Ic 2 ) \\ = ( Vc 1 - ( Vc 2 + ( Vc {1}^{′} - Vc {2}^{′} ) ) ) / ( Ic 1 - Ic 2 )\end{matrix}$$

The value obtained by subtracting the voltage value Vc2′ from the voltage value Vc1′ is equivalent to the variation ΔV in voltage component generated by the electromotive force of the secondary battery B in the voltage value between both electrodes of the secondary battery B generated in the period from the passage of the first detection current i1 to the passage of the second detection current i2. In other words, the voltage value between both electrodes of the secondary battery B varies (decreases) by the variation ΔV in the period from the passage of the first detection current i1 to the passage of the second detection current i2. Thus, correcting, with the variation, the voltage value Vc2 between both electrodes of the secondary battery B when the second detection current i2 passes can cancel the variation in the voltage value between both electrodes of the secondary battery B. The variation ΔV and the internal resistance r are actually calculated at the same time with the above expression in the present embodiment.

Then, the control unit 30 detects the state of health SOH of the secondary battery B in accordance with the internal resistance r of the secondary battery B, and stores the detected state of health SOH in the RAM (T230). Then, the process of the present flowchart is terminated. In other words, the state of health SOH is detected in consideration of the variation in the voltage value between both electrodes of the secondary battery B toward the open circuit voltage value OCV also in the battery-state detection process.

FIG. 5 schematically illustrates the waveforms of the voltage v, first detection current i1, and second detection current i2 between both electrodes of the secondary battery B during the battery-state detection process.

According to the present embodiment as described above, the current-passage state S that is the accumulated amount of the charging or discharging current through the secondary battery B just before the passage of the current stops is detected. The voltage value Va between both electrodes of the secondary battery B after the passage of the charging or discharging current is stopped, is measured. The elapsed time Ta from the time when the passage of the charging or discharging current is stopped to the time when the voltage value Va between both electrodes of the secondary battery B is measured, is measured. The open circuit voltage value OCV is estimated with the detected current-passage state S, the measured voltage value Va, the measured elapsed time Ta, and the open circuit voltage value relationship information J. The open circuit voltage value relationship information J is prepared for each of the current-passage states S just before the passage of the charging or discharging current stops and previously stored in the ROM in the control unit 30. The open circuit voltage value relationship information J is about the relationship between the transition of the voltage value between both electrodes of the secondary battery B after the passage of the current is stopped and the open circuit voltage value OCV of the secondary battery B. Then, the state of charge SOC of the battery is estimated in accordance with the estimated open circuit voltage value OCV.

The estimation as described above allows for the acquisition of an open circuit voltage value OCV with a high degree of accuracy in consideration of the variation in voltage between both electrodes of the secondary battery B generated by the electromotive force of the battery after the passage of the current is stopped, for example, by previously obtaining, from a preliminary measurement or a simulation, the relationship between the transition of the voltage value between both electrodes of the secondary battery B after the passage of the charging or discharging current is stopped and the open circuit voltage value OCV of the battery, and estimating the open circuit voltage value OCV of the battery from the open circuit voltage value relationship information J about the relationship because the relationship has repeatability. Thus, estimating the state of charge SOC of the secondary battery B in accordance with the estimated open circuit voltage value OCV can further improve the accuracy of estimation of the state of charge SOC.

Furthermore, the temperature Temp of the secondary battery B is measured. Furthermore, the open circuit voltage value relationship information J is prepared for each of the temperatures of the secondary battery B, and is stored in the ROM of the control unit 30. Then, the measured temperature Temp is also used to estimate the open circuit voltage value OCV. This allows for the acquisition of the open circuit voltage value OCV with a higher degree of accuracy by estimating the open circuit voltage value OCV also in consideration of the temperature of the secondary battery B because the voltage value between both electrodes of the secondary battery B relates also to the temperature of the secondary battery B. Thus, estimating the state of charge SOC of the secondary battery B in accordance with the estimated open circuit voltage value OCV can further improve the accuracy of estimation of the state of charge SOC.

Furthermore, the state of health SOH of the secondary battery B is detected. Furthermore, the open circuit voltage value relationship information J is prepared for each of the states of health SOH of the secondary battery B, and is stored in the ROM of the control unit 30. Then, the detected state of health SOH is also used to estimate the open circuit voltage value OCV. This allows for the acquisition of the open circuit voltage value OCV with a higher degree of accuracy by estimating the open circuit voltage value OCV also in consideration of the state of health SOH of the secondary battery B because the voltage value between both electrodes of the secondary battery B relates also to the state of health SOH of the secondary battery B. Thus, estimating the state of charge SOC of the secondary battery B also in accordance with the estimated open circuit voltage value OCV can further improve the accuracy of estimation of the state of charge SOC.

The present invention has been described above with a preferred embodiment. However, the battery state of charge estimation apparatus and the battery state of charge estimation method according to the present invention are not limited to the embodiment.

For example, in the embodiment described above, the elapsed time Ta from the time when the passage of the current through the secondary battery B is stopped to the time when the voltage value Va between both electrodes of the secondary battery B is measured, is measured. However, the time to be measured is not limited to the embodiment. Instead of the measurement of the elapsed time Ta, for example, it can be assumed that the voltage value Va between both electrodes of the secondary battery B is measured at the time when a predetermined measurement waiting period Tb elapses from the time when the passage of the current through the secondary battery B is stopped, and thus the open circuit voltage value relationship information J can be about the relationship between the voltage value between both electrodes of the secondary battery B when the measurement waiting period Tb elapses from the time when the passage of the current is stopped and the open circuit voltage value OCV of the secondary battery B. The configuration as described above brings about a similar operational effect to the embodiment, and has an advantage in terms of the processing load for estimating the state of charge, and the size of storage capacity for the open circuit voltage value relationship information J.

The temperature Temp of the secondary battery B is measured and used to estimate the open circuit voltage value OCV in the embodiment. However, for example, when the temperature of the secondary battery B varies slightly, the measurement of the temperature and the usage of the measured temperature for estimating the open circuit voltage value can be omitted. The state of health SOH of the secondary battery B can similarly be omitted.

In the embodiment described above, the apparatus is configured to detect itself the state of health SOH of the secondary battery B. However, instead, the apparatus can be configured to detect the state of health SOH by obtaining the state of health SOH of the secondary battery B that is detected by another device via the in-vehicle network. As long as the configuration is not contrary to an objective of the present invention, any method for detecting the state of health SOH of the secondary battery B is arbitrarily used.

In the embodiment described above, the current flowing in the charging direction is used as the first detection current i1 and the second detection current i2 for the battery-state detection process. However, the current flowing in the discharging direction can be used as the detection currents.

In the embodiment described above, the voltage value Vc1′ between both electrodes of the secondary battery B just before the passage of the first detection current i1 starts and the voltage value Vc2′ between both electrodes of the secondary battery B just before the passage of the second detection current i2 starts are measured in the battery-state detection process. However, the voltage value between both electrodes of the secondary battery B just after the passage of the first detection current i1 is stopped can be used as the voltage value Vc1′, and the voltage value between both electrodes of the secondary battery B just after the passage of the second detection current i2 is stopped can be used as the voltage value Vc2′.

Note that the embodiment is merely a typical mode of the present invention, and thus the present invention is not limited to the embodiment. In other words, a person skilled in the art can variously modify and implement the present invention in accordance with the publicly known knowledge without departing from the gist of the present invention. Needless to say, the modification is included in the scope of the present invention as long as the modification includes the configuration of the battery state of charge estimation apparatus and the battery state of charge estimation method according to the present invention.

### REFERENCE SIGNS LIST

1 Battery state of charge estimation apparatus
15 Charging unit
21 Current measurement unit
22 Voltage measurement unit
23 Temperature measurement unit
24 First analog-digital converter
25 Second analog-digital converter
26 Third analog-digital converter
30 Control unit (Current-passage state detection section, Voltage value measurement section, Elapsed time measurement section, Open circuit voltage value estimation section, State of charge estimation section, State of health detection section, Temperature measurement section, and Relationship information storage section)
B Secondary battery (Battery)

1. A battery state of charge estimation apparatus that estimates a state of charge of a battery, the apparatus comprising:
a current-passage state detection section that detects a current-passage state, the current-passage state corresponding to an accumulated amount of charging or discharging current flowing through the battery for a predetermined period of time just before passage of the current stops;
a voltage value measurement section that measures a voltage value between both electrode of the battery after the passage of the current is stopped;
an elapsed time measurement section that measures an elapsed time from a time when the passage of the current is stopped to a time when the voltage value is measured by the voltage value measurement section;
a relationship information storage section that previously stores open circuit voltage value relationship information, the open circuit voltage value relationship information being prepared for each of a plurality of the current-passage states just before the passage of the current stops, the open circuit voltage value relationship information being about a relationship between transition of the voltage value between both electrode of the battery after the passage of the current is stopped and an open circuit voltage value of the battery;
an open circuit voltage value estimation section that estimates the open circuit voltage value with the current-passage state detected with the current-passage state detection section, the voltage value measured with the voltage value measurement section, the elapsed time measured with the elapsed time measurement section, and the open circuit voltage value relationship information stored in the relationship information storage section; and
a state of charge estimation section that estimates the state of charge of the battery in accordance with the open circuit voltage value estimated with the open circuit voltage value estimation section.

2. A battery state of charge estimation apparatus that estimates a state of charge of a battery, the apparatus comprising:
a current-passage state detection section that detects a current-passage state, the current-passage state corresponding to an accumulated amount of charging or discharging current flowing through the battery for a predetermined period of time just before passage of the current stops;
a voltage value measurement section that measures a voltage value between both electrodes of the battery when a predetermined measurement waiting period elapses from a time when the passage of the current is stopped;
a relationship information storage section that previously stores open circuit voltage value relationship information, the open circuit voltage value relationship information being prepared for each of a plurality of the current-passage states just before the passage of the current stops, the open circuit voltage value relationship information being about a relationship between the voltage value between both electrode of the battery when the measurement waiting period elapses from the time when the passage of the current is stopped and an open circuit voltage value of the battery;
an open circuit voltage value estimation section that estimates the open circuit voltage value with the current-passage state detected with the current-passage state detection section, the voltage value measured with the voltage value measurement section, and the open circuit voltage value relationship information stored in the relationship information storage section; and
a state of charge estimation section that estimates the state of charge of the battery in accordance with the open circuit voltage value estimated with the open circuit voltage value estimation section.

3. The battery state of charge estimation apparatus according to claim 1, further comprising a temperature measurement section that measures a temperature of the battery,
wherein the relationship information storage section further stores the open circuit voltage value relationship information for each of the temperatures of the battery, and
the open circuit voltage value estimation section also uses the temperature measured with the temperature measurement section to estimate the open circuit voltage value.

4. The battery state of charge estimation apparatus according to claim 2, further comprising a temperature measurement section that measures a temperature of the battery,
wherein the relationship information storage section further stores the open circuit voltage value relationship information for each of the temperatures of the battery, and
the open circuit voltage value estimation section also uses the temperature measured with the temperature measurement section to estimate the open circuit voltage value.

5. The battery state of charge estimation apparatus according to claim 1, further comprising a state of health detection section that detects a state of health of the battery,
wherein the relationship information storage section further stores the open circuit voltage value relationship information for each of the states of health of the battery, and
the open circuit voltage value estimation section also uses the state of health detected with the state of health detection section to estimate the open circuit voltage value.

6. The battery state of charge estimation apparatus according to any one of claim 2, further comprising a state of health detection section that detects a state of health of the battery,
wherein the relationship information storage section further stores the open circuit voltage value relationship information for each of the states of health of the battery, and
the open circuit voltage value estimation section also uses the state of health detected with the state of health detection section to estimate the open circuit voltage value.

7. The battery state of charge estimation apparatus according to claim 3, further comprising a state of health detection section that detects a state of health of the battery,
wherein the relationship information storage section further stores the open circuit voltage value relationship information for each of the states of health of the battery, and
the open circuit voltage value estimation section also uses the state of health detected with the state of health detection section to estimate the open circuit voltage value.

8. The battery state of charge estimation apparatus according to claim 4, further comprising a state of health detection section that detects a state of health of the battery,
wherein the relationship information storage section further stores the open circuit voltage value relationship information for each of the states of health of the battery, and
the open circuit voltage value estimation section also uses the state of health detected with the state of health detection section to estimate the open circuit voltage value.

9. A battery state of charge estimation method for estimating a state of charge of a battery, the method comprising:
detecting a current-passage state, the current-passage state corresponding to an accumulated amount of charging or discharging current flowing through the battery for a predetermined period of time just before passage of the current stops;
measuring a voltage value between both electrode of the battery after the passage of the current is stopped;
measuring an elapsed time from a time when the passage of the current stops to a time when the voltage value is measured in the voltage value measurement;
estimating an open circuit voltage value with the current-passage state detected in the current-passage state detection, the voltage value measured in the voltage value measurement, the elapsed time measured in the elapsed time measurement, and open circuit voltage value relationship information, the open circuit voltage value relationship information being prepared for a current-passage state or each of a plurality of the current-passage states just before the passage of the current stops, the open circuit voltage value relationship information being previously stored in a storage section, the open circuit voltage value relationship information being about a relationship between transition of the voltage value between both electrodes of the battery after the passage of the current is stopped and the open circuit voltage value of the battery; and
estimating the state of charge of the battery in accordance with the open circuit voltage value estimated in the open circuit voltage value estimation.
